(19) United States
(12) Patent Application Publication
(10) Pub. No.: US 2012/0269959 A1
(43) Pub. Date: Oct. 25, 2012

(54) SCREEN PRINTING APPARATUS AND SCREEN PRINTING METHOD

(75) Inventors: Tetsuya Tanaka, Yamanashi (JP); Yuji Otake, Yamanashi (JP)

(73) Assignee: Panasonic Corporation, Osaka (JP)

(21) Appl. No.: 13/265,611

(22) PCT Filed: Mar. 18, 2011
(86) PCT No.: PCT/JP2011/001653

§ 371 Date: Oct. 21, 2011

(30) Foreign Application Priority Data
Mar. 24, 2010 (JP) 2010-068254

(51) Int. Cl. H05K 3/12

(52) U.S. Cl. 427/98.4; 118/200

(57) ABSTRACT

There are provided a screen printing apparatus and a screen printing method which can realize an increase in conversion efficiency of a solar cell by forming a circuit pattern having a large aspect ratio of a sectional shape by increasing the thickness of the circuit pattern. A screen printing apparatus 10 and a screen printing method for forming a belt-shaped circuit pattern on a surface of a substrate 11 include a support table 12 which supports the substrate, a metal mask 1 having a covering portion which covers a part of the surface of the substrate 11, a plurality of apertures from which a part of the substrate 11 is exposed and bridge portions which are provided between the apertures along a direction which intersects a longitudinal direction of a circuit pattern to be formed and a cartridge-type squeegee head 13 which supplies a paste which constitutes a circuit pattern to a surface of the metal mask 1 under a predetermined pressure while causing a squeegee 14 of a predetermined length to slide on an upper surface of the metal mask 1 in a contact fashion.

### TECHNICAL FIELD

The present invention relates to a screen printing apparatus and a screen printing method for printing a paste such as a solder paste or a conductive paste on a substrate and more particularly to a screen printing apparatus and a screen printing method which are applied in forming electrodes of a solar cell.

### BACKGROUND ART

Conventionally, there have been known screen printing apparatuses and screen printing methods which employ a mesh mask for printing to form electrodes (refer to Patent Literature 1, for example).

### RELATED ART LITERATURE

### Patent Literature

Patent Literature (PTL) 1: JP-A-2007-62079 (FIG. 1, Paragraph 0052)

### SUMMARY OF THE INVENTION

### Problem that the Invention is to Solve

In order to increase the conversion efficiency of a solar cell, it is effective to increase the light receiving area of the solar cell by thinning electrodes thereof. However, a thinned electrode increases extremely electrical resistance and calls for a deterioration in performance, which decreases the conversion efficiency on the contrary. Thus, the thickness of an electrode to be printed needs to be increased.

In the screen printing apparatus and screen printing method of PTL 1 above, however, a mesh provided in an opening portion in a mesh screen constitutes resistance to thereby decrease the mesh aperture, and therefore, the thickness of the printed electrode formed by use of this mesh mask is thinned.

Consequently, there are fears that the conversion efficiency of a solar cell which is produced by use of the screen printing apparatus and the screen printing method of PTL 1 is decreased.

The invention has been made with a view to solving the problem described above, and an object thereof is to provide a screen printing apparatus and a screen printing method which can realize an increase in conversion efficiency of a solar cell to be produced by forming a circuit pattern having a large aspect ratio of a sectional shape by increasing the thickness thereof.

### Means for Solving the Problem

According to the invention, there is provided a screen printing apparatus for forming a belt-shaped circuit pattern on a surface of a substrate comprising: a support table for supporting the substrate; a metal mask having a covering portion for covering a part of the surface of the substrate, a plurality of apertures from which a part of the substrate is exposed and bridge portions provided individually between the apertures along a direction which intersects a longitudinal direction of the circuit patterns; and a cartridge-type squeegee head for supplying a paste to be the circuit pattern to a surface of the metal mask under a predetermined pressure while causing a squeegee of a predetermined length to slide relatively on an upper surface of the metal mask in a contact fashion.

In the invention, the squeegee head supplies the paste to the surface of the metal mask under the predetermined pressure while causing the squeegee of the predetermined length to slide relatively on the upper surface of the metal mask in a contact fashion.

Consequently, in the invention, compared with the conventional screen printing apparatus which employs the mesh mask, a circuit pattern having a large aspect ratio of a sectional shape is formed by increasing the thickness of the circuit pattern, thereby making it possible to realize an increase in the conversion efficiency of a solar cell to be produced.

According the invention, there is provided a screen printing apparatus as set forth above, wherein a lower surface of the bridge portion constitutes a depressed step surface relative to a lower surface of the covering portion.

In the invention, the lower surface of the bridge portion constitutes the depressed step surface, and therefore, the paste is filled between the substrate and the bridge portion through the aperture, whereby the belt-shaped circuit pattern can be formed.

According to the invention, there is provided a screen printing method for forming a belt-shaped circuit pattern on a surface of a substrate comprising the steps of: causing the substrate to be supported on a support table; placing a metal mask having a covering portion for covering a part of the surface of the substrate, a plurality of apertures from which a part of the substrate is exposed and bridge portions provided individually between the apertures along a direction which intersects a longitudinal direction of the circuit patterns on a surface of the substrate; and supplying a paste to be the circuit pattern to a surface of the metal mask under a predetermined pressure by a cartridge-type squeegee head while causing a squeegee of a predetermined length to slide relatively on an upper surface of the metal mask in a contact fashion.

In this invention, the squeegee head supplies the paste to the surface of the metal mask under the predetermined pressure while causing the squeegee of the predetermined length to slide relatively on the upper surface of the metal mask in a contact fashion.

Consequently, in the invention, compared with the conventional screen printing apparatus which employs the mesh mask, a circuit pattern having a large aspect ratio of a sectional shape is formed by increasing the thickness of the circuit pattern, thereby making it possible to realize an increase in the conversion efficiency of a solar cell to be produced.

### Advantageous Effects of the Invention

According to the screen printing apparatus and the screen printing method of the invention, the squeegee head supplies the paste to the surface of the metal mask under the predetermined pressure while causing the squeegee of the predetermined length to slide relatively on the upper surface of the metal mask in a contact fashion.

By adopting this configuration, according to the screen printing apparatus and the screen printing method of the invention, there is provided an advantageous effect that compared with the conventional screen printing apparatus which employs the mesh mask, a circuit pattern having a large aspect ratio of a sectional shape is formed by increasing the thickness of the circuit pattern, thereby making it possible to realize an increase in the conversion efficiency of a solar cell to be produced.

### DESCRIPTION OF THE DRAWINGS

FIG. 1 is a front view of a screen printing apparatus having an open-type squeegee to which a screen printing method according to an embodiment of the invention is applied.

FIG. 2 is a front view of a screen printing apparatus having a cartridge-type squeegee to which the screen printing method in FIG. 1 is applied.

FIG. 3 is a side view of the screen printing apparatus in FIG. 1.

FIG. 4 is a plan view of the screen printing apparatus in FIG. 1.

FIG. 5 is a plan view of a metal mask which is applied to the screen printing apparatus in FIG. 1.

FIG. 6 is an enlarged view of the metal mask in FIG. 5.

FIG. 7 is an enlarged view of a main part of the metal mask in FIG. 5.

FIG. 8 is a sectional view taken along the line A-A in FIG. 7.

FIG. 9 is a sectional view taken along the line B-B in FIG. 7.

FIG. 10 is a perspective view showing an external appearance of the periphery of the bridge portion of the metal mask in FIG. 5.

FIG. 11 is a perspective view showing an external appearance of the periphery of a bridge portion according to a modified example to the metal mask in FIG. 5.

FIG. 12 is a plan view of a main part of a modified example to the screen printing apparatus in FIG. 1.

FIG. 13 is a plan view of a modified example to the metal mask in FIG. 5.

FIG. 14 is a plan view of another modified example to the metal mask in FIG. 5.

FIG. 15 is a plan view of a further modified example to the metal mask in FIG. 5.

### MODE FOR CARRYING OUT THE INVENTION

Hereinafter, a screen printing apparatus and a screen printing method according to an embodiment of the invention will be described by reference to the drawings.

A screen printing apparatus 10 to which a screen printing method according to an embodiment of the invention includes a substrate 11, a support table 12 which supports the substrate 11, a metal mask 1, a squeegee head 13 for supplying a paste P which constitutes a circuit pattern to a surface of the metal mask 1 while causing squeegees 14 of a predetermined length to slide relatively on an upper surface of the metal mask 1 in a contact fashion, and a cleaning mechanism 15 for cleaning a lower surface of the metal mask 1.

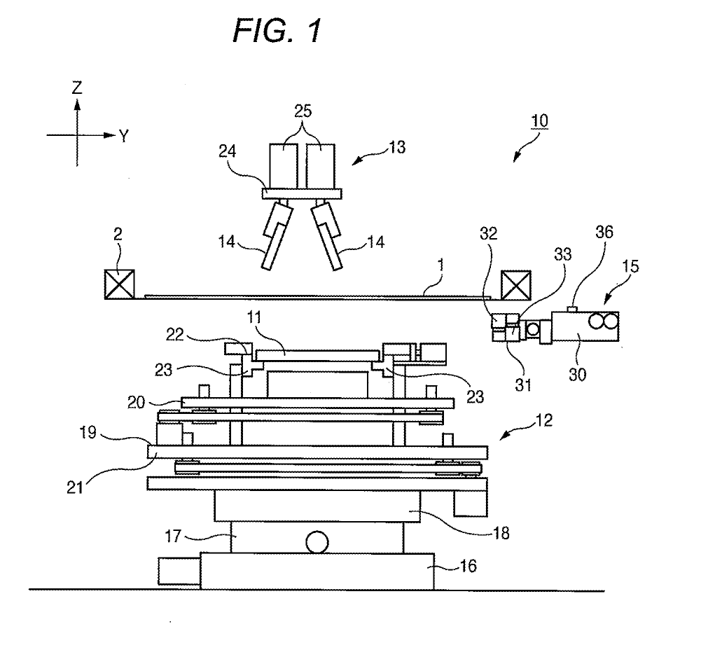

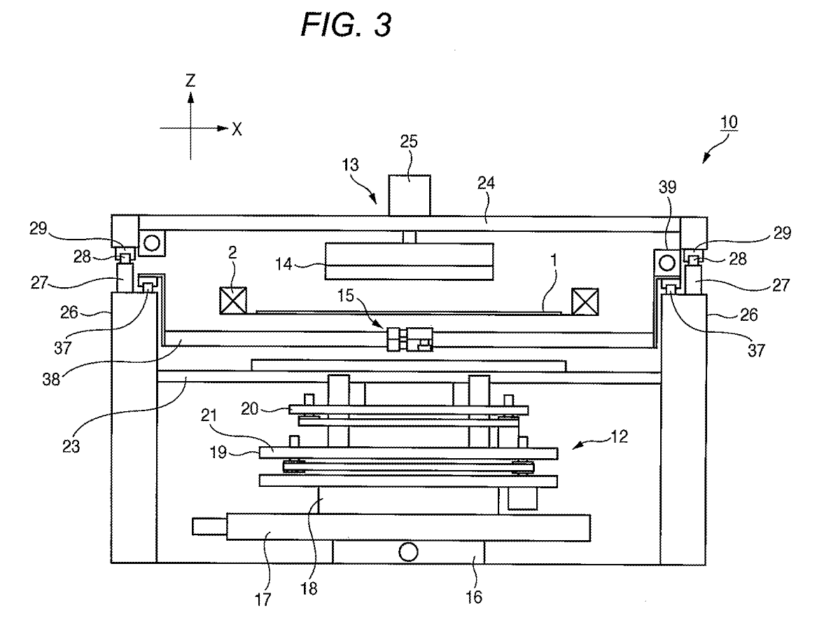

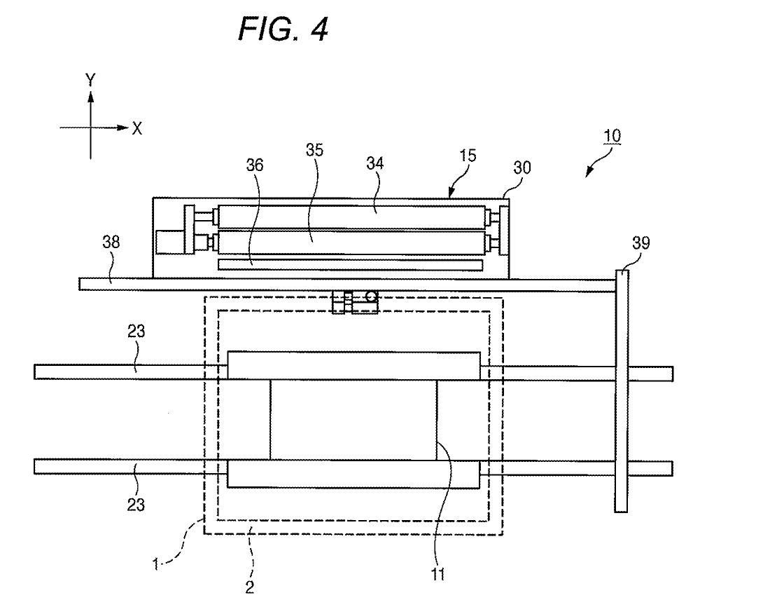

As is shown in FIGS. 1, 2, 3 and 4, in the screen printing apparatus 10, the support table 12, which is a positioning means for positioning a substrate 11, is made up of a Y-axis table 16, an X-axis table 17 and a θ-axis table 18 which are stacked one on another. In addition, a first Z-axis table 19 and a second Z-axis table 20 are stacked further on those tables to work in combination therewith.

The first Z-axis table 19 has a horizontal base plate 21, and a substrate 11, which is a printing target, is carried while being supported at both end portions by two carrier rails 23 which are disposed in parallel with a substrate carrying direction (an X direction) at a substrate carrier portion 22 on the base plate 21. The base carrier portion 22 extends to an upstream side and a downstream side, and a substrate 11 which is carried in from the upstream side is carried by the base carrier portion 22 and is further positioned by the support table 12. The substrate 11 on which a required printing has been executed is carried out to the downstream side by the carrier rails 23.

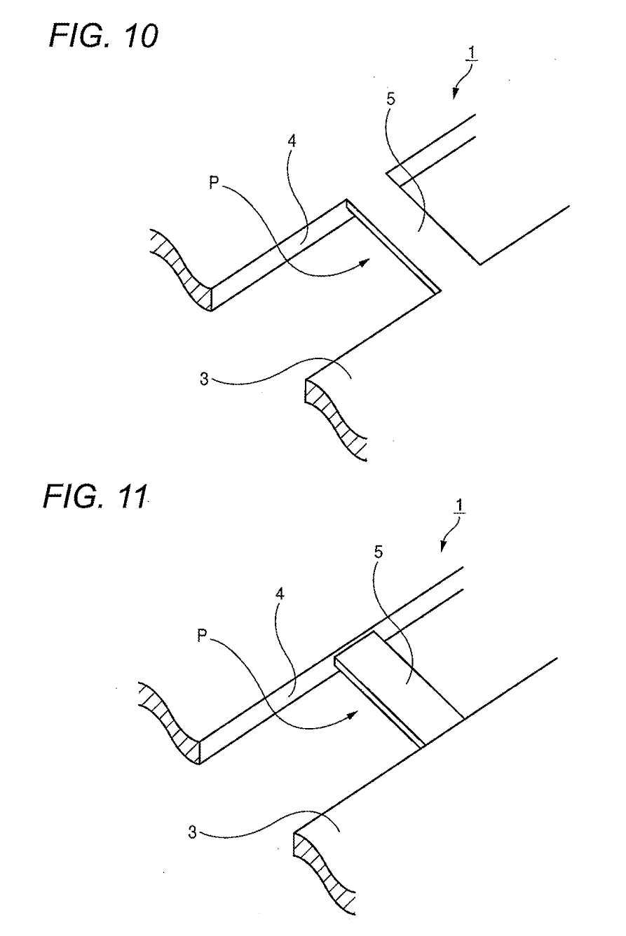

The metal mask 1 is stretched to be deployed in a mask frame 2. The squeegee head 13 is disposed above the metal mask 1. The squeegee head 13 is of an open type, and a squeegee lifting mechanism 25 is provided on a horizontal plate 24 for lifting up or down the squeegees 14 of the predetermined length. The squeegee head 13 supplies a paste (refer to FIG. 10) P which constitutes a circuit pattern to a surface of the metal mask 1 under a predetermined pressure, and when the squeegee lifting mechanism 25 is driven, the squeegees 14 are lifted down to be brought into abutment with an upper surface of the metal mask 1.

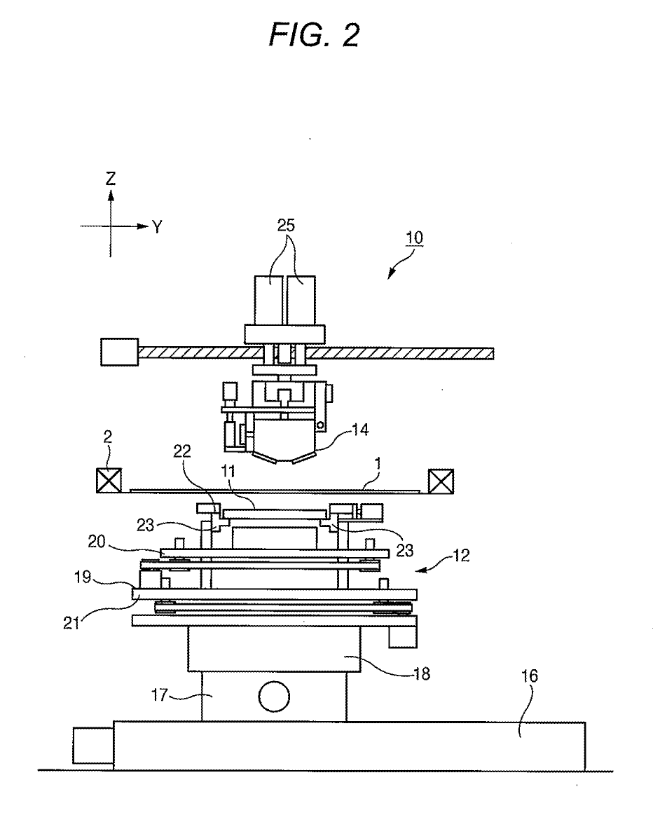

FIG. 2 shows a screen printing apparatus 10 which is equipped with a cartridge-type squeegee head 13 in place of the open-type squeegee head 13. As in the aforesaid screen printing apparatus 10, in this printing apparatus 10, too, the squeegee head 13 supplies a paste (refer to FIG. 10) P which constitutes a circuit pattern to a surface of a metal mask 1 under a predetermined pressure. Then, when a squeegee lifting mechanism 25 is driven, a squeegee 14 is lifted down to be brought into abutment with an upper surface of the metal mask 1. The cartridge-type squeegee head 13 is superior in filling performance to the open-type squeegee head 13.

Brackets 27 are provided on vertical frames 26, and guide rails 28 are provided individually on the brackets 27 so as to extend in a Y direction. Sliders 29, which are fitted individually on the corresponding guide rails 28 in a slidable fashion, are connected to corresponding ends of the plate 24, whereby the squeegee head 13 is slidable in the Y direction.

In the cleaning mechanism 15, a cleaning head unit 30 moves together with a camera head unit 31 for capturing images of the a substrate 11 and the metal task 1. The camera head unit 31 includes a substrate recognition camera 32 for capturing an image of a substrate 11 from thereabove and a mask recognition camera 33 for capturing an image of the metal mask 1 from a lower surface side thereof and can recognize a substrate 11 and the metal mask 1 simultaneously when the camera head unit 30 moves.

Provided on the cleaning head unit 30 are a paper roll 34 around which non-used cleaning paper is wound, a paper roll 35 around which used cleaning paper is wound, and a cleaning nozzle 36 which sets a cleaning area of a predetermined length on a lower surface of the metal mask 1. The cleaning head unit 30 is supported on a head X-axis table 38 which is slidably assembled to guide rails 37 on the vertical frames 26 so as to be moved horizontally in the Y direction by a head X-axis moving mechanism 39 on the head X-axis table 38.

When in a waiting position, the cleaning head unit 30 is withdrawn to a side of the support table 12. When executing a cleaning operation, the cleaning head unit 30 is caused to advance to a position below the metal mask 1 together with the camera head unit 31, and following this, the cleaning head unit 30 is caused to rise. Then, the cleaning head unit 30 is moved horizontally in such a state that the non-used cleaning paper is pressed against the lower surface of the metal mask 1 by the cleaning nozzle 36, whereby a cleaning operation is executed.

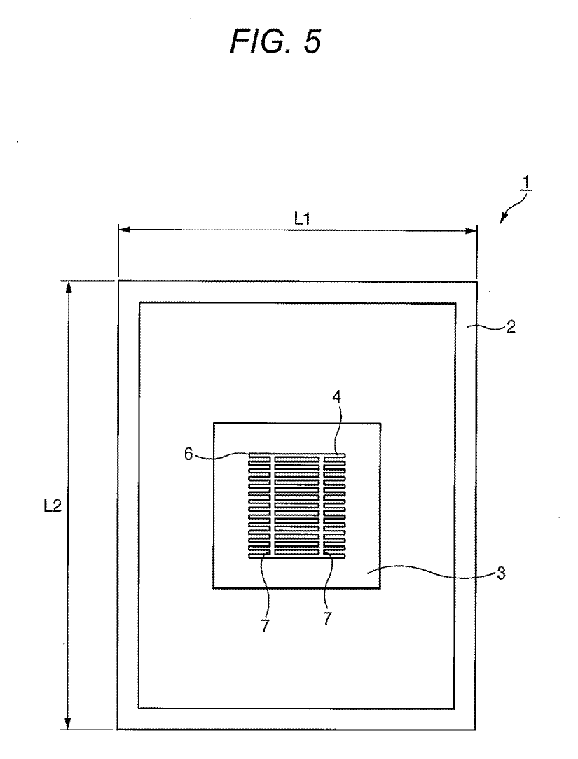

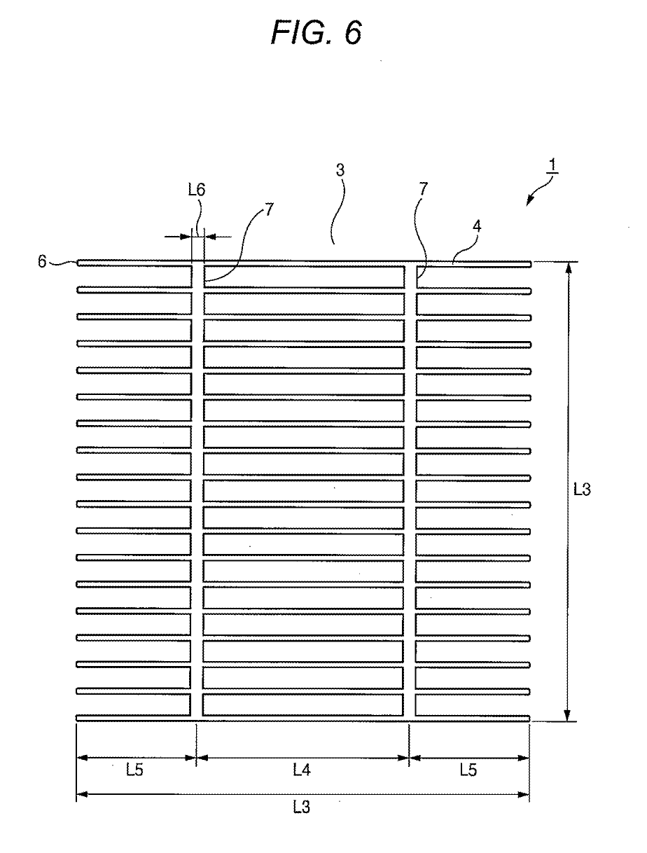

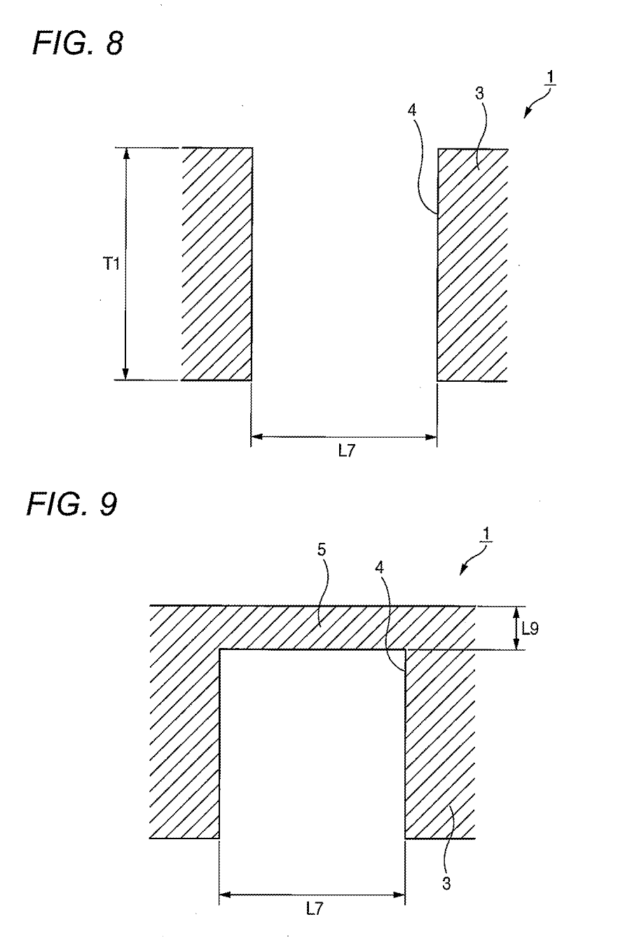

Next, the metal mask 1 will be described in detail. As is shown in FIGS. 5, 6, 7, 8, 9 and 10, the metal mask 1 has, for example, a thickness dimension T1 of 0.1 mm, a width dimension L1 of 550 mm and a length dimension L2 of 650 mm. The metal mask 1 has a covering portion 3 which is provided inside the mask frame 2 for covering a part of a surface of a substrate 11 and a plurality of rectangular apertures 4 from which a part of the substrate 11 is exposed. The metal mask 1 also has bridge portions 5 which are provided between the apertures 4 so as to extend along a direction which intersects a longitudinal direction of a circuit pattern to be formed. The metal mask 1 has a plurality of grid portion 6 where the apertures 4 and the bridge portions 5 are provided and which are arranged parallel to each other. The metal mask 1 also has belt-shaped bus-bar portions 7 which are continuous with terminal end apertures 4 at longitudinal end portions of the grid portions 6.

There are provided 67 grid portions 6 which each have a line width of 0.08 mm, for example. The bus-bar portions 7 each having a width dimension L6 of 2 mm are disposed within a width dimension L3 of 153 mm in the longitudinal direction of the grid portions 6 in positions lying 39 mm away from the left and right ends of the grid portions 6 with central portions having a width dimension L4 of 75 mm disposed therebetween. The aperture 4 has a width dimension L7 of 0.08 mm, for example. The bridge portion 5 has a width dimension L8 of 0.05 mm, for example, and a height dimension L9 of 0.02 mm, for example. In addition, the bridge portion 5 has a height dimension L9 of 0.02 mm, for example, at an end portion of the aperture 4 having a thickness dimension T1 of 0.1 mm, for example, and therefore, a lower surface of the aperture 4 is formed into a depressed step surface relative to a lower surface of the covering portion 3.

As is shown in a modified example of a metal mask 1 shown in FIG. 11, a bridge portion 5 may be disposed at a central portion in a thickness direction of an aperture 4. In this case, too, a lower surface of the bridge portion 5 is formed into a depressed step surface relative to a lower surface of a covering portion 3.

Next, a solar cell electrode forming system to which the screen printing apparatus 10 is applied and a solar cell electrode forming method to which the screen printing method is applied will be described. In the solar cell electrode forming method, a screen printing step in which the cartridge-type squeegee head is used and a calcining step are performed.

In the screen printing step, when a substrate 11 is carried in to a printing position by the substrate carrier portion 22, the second Z-axis table 20 is driven so that a lower surface of the substrate 11 is supported from therebelow. Then, in this state, the substrate 11 is registered with the metal mask 1 by the support table 12, and the metal mask 1 is brought into face contact with an upper surface of the metal mask 1. As this occurs, the squeegee head 13 disposes the squeegee 14 relative to the metal mask 1 so that a longitudinal direction of the squeegee 14 follows a direction which is at right angles to the direction in which the apertures 4 and the bridge portions 5 are arranged in the metal mask 1. Then, when the squeegee 14 is caused to slide in the Y direction relative to the metal mask 1 along the direction in which the apertures 4 and the bridge portions 5 are arranged while a paste is being supplied on the metal mask 1 under a predetermined pressure which is applied by the squeegee 14, an on-contact printing is performed with the substrate 11 kept in contact with the metal mask 1. As this occurs, the paste P is filled sufficiently into the apertures 4 including portions lying below the bridge portions 5 by being pushed into the portions lying below bridge portions 5 under pressure from the apertures 4 as the squeegee 14 moves in the Y direction. The substrate 11 on which the printing is completed is carried out to the calcining step on the downstream side by the carrier rails 23.

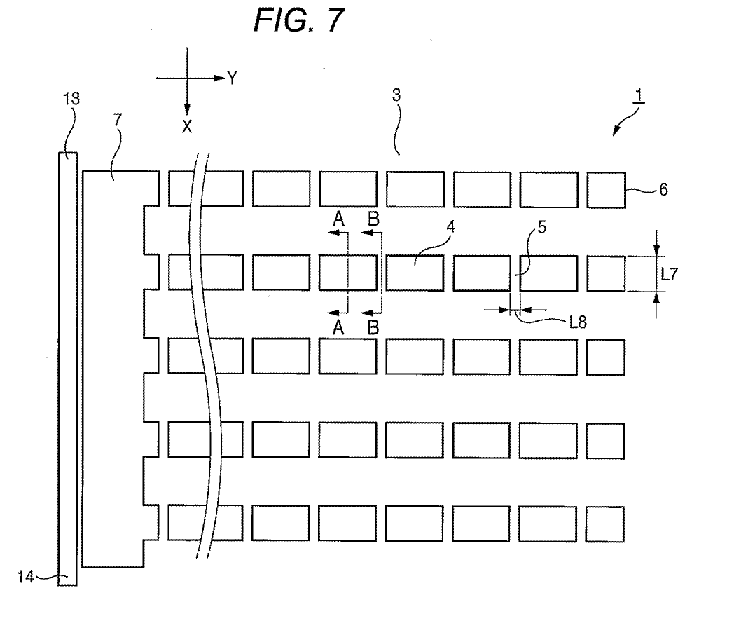

Namely, as is shown in FIG. 7, the squeegee head 13 disposes the squeegee 14 relative to the metal mask 1 so that the longitudinal direction of the squeegee 14 follows the direction which is at right angles to the direction in which the apertures 4 and the bridge portions 5 are arranged in the metal mask 1. Then, when the squeegee 14 is caused to slide in the Y direction relative to the metal mask 1 along the direction in which the apertures 4 and the bridge portions 5 are arranged while the paste is being supplied on the metal mask 1 under the predetermined pressure which is applied by the squeegee 14, the on-contact printing is performed with the substrate 11 kept in contact with the metal mask 1.

The paste P is pushed into the portions lying below the bridge portions 5 under pressure from the apertures 4 by being supplied to the surface of the metal mask 1 under the predetermined pressure by the cartridge-type squeegee head 13, whereby the paste P is filled sufficiently into the apertures 4 including the portions lying below the bridge portions 5.

Next, the calcining step, calcining is executed in such a state that the paste P is placed on the surface of the substrate 11 while being formed into a predetermined shape. By calcining the paste P in that way, the paste P is formed into an electrode for a solar cell. As this occurs, by employing the cartridge-type squeegee head 13 in the screen printing step to form the electrode, the screen printing step and the calcining step are each performed once. Then, by employing the cartridge-type squeegee head 13 in the screen printing step, the electrode is formed in which an aspect ratio of a sectional shape is set to be not less than 1.0.

When cleaning is performed in the screen printing apparatus 10 in which printing is completed, a longitudinal direction of the cleaning nozzle 36 of the cleaning head unit 30 is disposed parallel to a longitudinal direction of the bus-bar portion 7 of the metal mask 1, and a lower surface of the metal mask 1 is cleaned.

As this occurs, the longitudinal direction of the cleaning nozzle 36 is disposed parallel to the longitudinal direction of the bus-bar portion 7 of the metal mask 1. Namely, since the bus-bar portion 7 is wider than the grid portion 6, an amount of residual paste on the bus-bar portion 7 is larger than an amount of residual paste on the grid portion 6. Because of this, by taking the nozzle disposition which gives priority to cleaning of the bus-bar portion 7 rather than to cleaning of the grid portion 6, the cleaning quality of the metal mask 1 can be increased in whole.

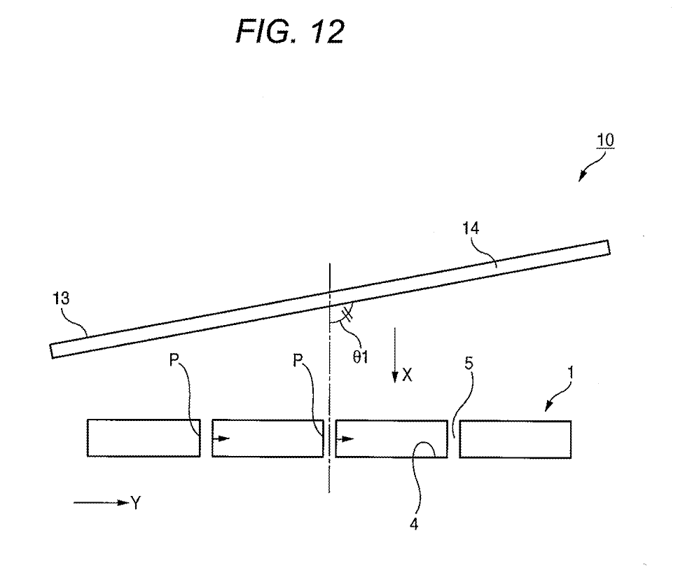

As is shown in FIG. 12, in a modified example of a screen printing apparatus 10, a metal mask 1 is employed in which bridge portions 5 are provided along a direction which intersects a longitudinal direction of a circuit pattern which is formed between apertures 4. A squeegee 14 is disposed relatively to the metal mask 1 so that a longitudinal direction of the squeegee 14 follows a direction which intersects a direction which is at right angles to a direction in which the apertures 4 and the bridge portions 5 are arranged at a predetermined angle θ1, and the squeegee 14 moves relatively along an X direction which is at right angles to the direction in which the apertures 4 and the bridge portions 5 are arranged. By moving the squeegee 14 from the direction which intersects the direction which is at right angles to the direction in which the apertures 4 and the bridge portions 5 are arranged at the predetermined angle θ1, the paste P is pushed obliquely downwards towards portions lying below the bridge portions 5 from the apertures 4 under pressure, whereby the paste P is filled sufficiently into the apertures 4 including the portions lying below the bridge portions 5.

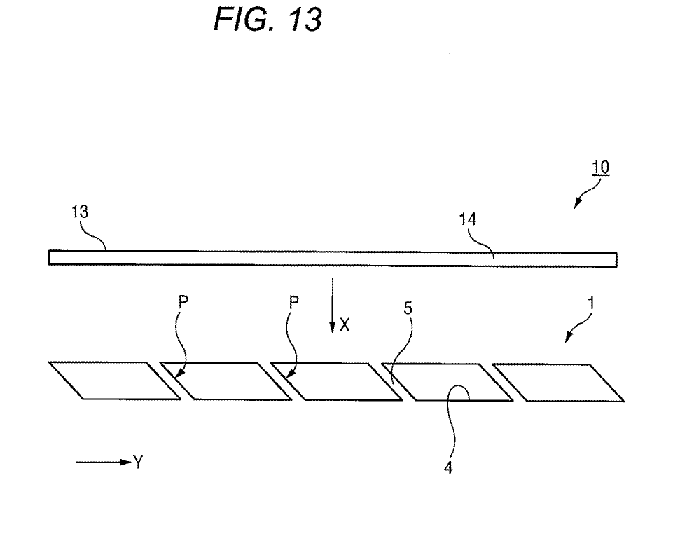

As is shown in FIG. 13, a modified example of a metal mask 1 has apertures 4 each having a parallelogram shape and arranged along a longitudinal direction of a circuit pattern to be formed. Because of this, bridge portions 5 are disposed inclined relative to a direction which is at right angles to the longitudinal direction of the circuit pattern to be formed. In this modified example, a squeegee 14 is disposed relatively to the metal mask 1 so that a longitudinal direction of the squeegee 14 follows a direction which is at right angles to a direction in which the apertures 4 and the bridge portions 5 of the metal mask 1 are arranged. Then, the squeegee 14 moves relative to the metal mask 1 along an X direction which is at right angles to the direction in which the apertures 4 and the bridge portions 5 are arranged. By adopting this configuration, a paste P is pushed from acute angle portions of the bridge portions 5 which are disposed inclined relative to the traveling direction of the squeegee 14 towards portions lying below the bridge portions 5 under pressure, whereby the paste P is filled sufficiently into the apertures 4 including the portions lying below the bridge portions 5. In addition, the squeegee 14 may move relative to the metal mask 1 in a Y direction which follows the direction in which the apertures 4 and the bridge portions 5 are arranged.

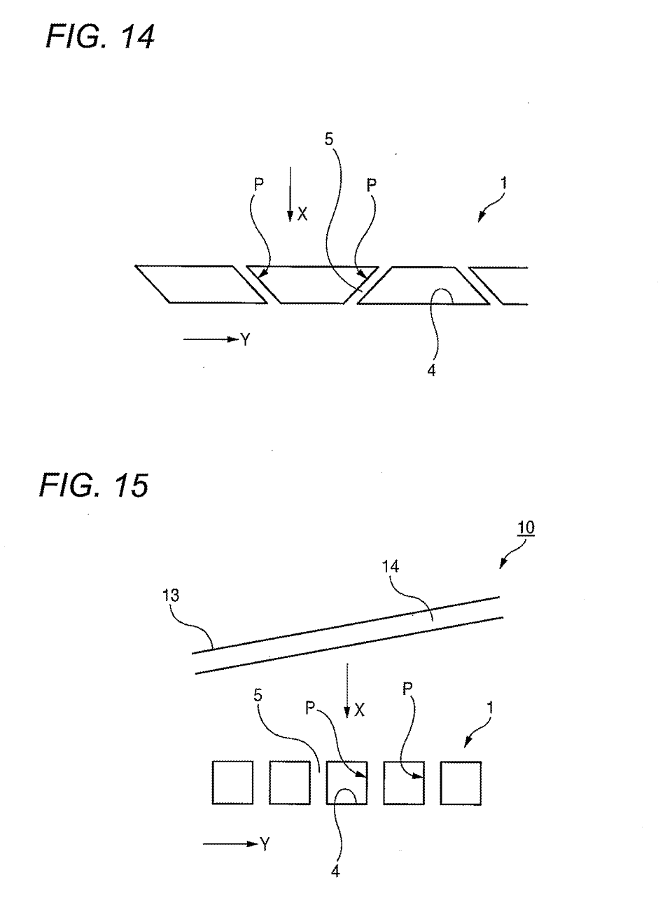

As is shown in FIG. 14, another modified example of a metal mask 1 has apertures 4 each having an isosceles trapezoidal shape and arranged along a longitudinal direction of a circuit pattern to be formed in such a way that an upper base of a trapezoidal aperture 4 follows a lower base of an adjacent one or a lower base of a trapezoidal aperture 4 follows an upper base of an adjacent one in an alternate fashion. Because of this, bridge portions 5 are disposed inclined relative to a direction which is at right angles to a longitudinal direction of the circuit pattern to be formed. In this modified example, a squeegee 14 is disposed relatively to the metal mask 1 so that a longitudinal direction of the squeegee 14 follows a direction which is at right angles to a direction in which the apertures 4 and the bridge portions 5 of the metal mask 1 are arranged. Then, the squeegee 14 moves relative to the metal mask 1 along the direction in which the apertures 4 and the bridge portions 5 are arranged. By adopting this configuration, a paste P is pushed from acute angle portions of the bridge portions 5 which are disposed inclined relative to the traveling direction of the squeegee 14 towards portions lying below the bridge portions 5 under pressure, whereby the paste P is filled sufficiently into the apertures 4 including the portions lying below the bridge portions 5. In addition, the squeegee 14 may move relative to the metal mask 1 in a Y direction which follows the direction in which the apertures 4 and the bridge portions 5 are arranged.

As is shown in FIG. 15, a further modified example of a metal mask 1 has square apertures 4 along a longitudinal direction of a circuit pattern to be formed. In this modified example, a squeegee 14 is disposed relatively to the metal mask 1 so that a longitudinal direction of the squeegee 14 follows a direction which intersects a direction which is at right angles to a direction in which the apertures 4 and bridge portions 5 of the metal mask 1 are arranged at a predetermined angle. Then, the squeegee 14 moves relatively along an X direction which is at right angles to the direction in which the apertures 4 and the bridge portions 5 are arranged of the metal mask 1. By adopting this configuration, a paste P is pushed in from the apertures 4 into portions lying below the bridge portions 5 under pressure as the squeegee 14 moves in the X direction, whereby the paste P is filled sufficiently into the apertures 4 including the portions lying below the bridge portions 5.

Thus, as has been described above, according to the screen printing apparatus 10 according to the embodiment of the invention, the squeegee head 13 supplies the paste to the surface of the metal mask 1 under the predetermined pressure while causing the squeegee 14 of the predetermined length to slide on the upper surface of the metal mask 1 in the contact fashion.

Consequently, according to the screen printing apparatus 10 according to the embodiment of the invention, compared with the conventional screen printing apparatus which employs the mesh mask, by employing the cartridge-type squeegee head 13 in the screen printing step, the thickness of the circuit pattern formed is increased so that the circuit pattern formed can have a large aspect ratio of a sectional shape thereof, thereby making it realize an increase in the conversion efficiency of a solar cell to be produced.

According to the screen printing apparatus 10 according to the embodiment of the invention, the lower surface of the bridge portion 5 is formed into the depressed step surface, and therefore, the paste is filled between the substrate 11 and the bridge portions 5 through the apertures 4, thereby making it possible to form the belt-shaped circuit pattern.

According to the screen printing method according to the embodiment of the invention, the squeegee head 13 supplies the paste to the surface of the metal mask 1 under the predetermined pressure while causing the squeegee 14 of the predetermined length to slide on the upper surface of the metal mask 1 in the contact fashion.

Consequently, according to the screen printing method according to the embodiment of the invention, compared with the conventional screen printing method which employs the mesh mask, by employing the cartridge-type squeegee head 13 in the screen printing step, the thickness of the circuit pattern formed is increased so that the circuit pattern formed can have a large aspect ratio of a sectional shape thereof, thereby making it realize an increase in the conversion efficiency of a solar cell to be produced.

### EXAMPLE

Next, an example will be described which was made in order to verify the function and advantage of the screen printing apparatus 10 and the screen printing method to which the solar cell electrode forming system according to the invention is applied. In this example, a comparison example 1 and a comparison example 2 were prepared to form electrodes for a solar cell. In the comparison example 1, a mesh mask having a mesh aperture of 50% or lower was used, and gap printing or off-contact printing was performed by use of the open-type squeegee head, and in the comparison example 2, a mesh mask having a mesh aperture of 50% or lower was used, and on-contact printing was performed by use of the cartridge-type squeegee head. Then, aspect ratios of sectional areas based on height dimensions and width dimensions of the electrodes formed were measured.

The results of the measurements show that the aspect ratio of the comparison example 1 was 0.3 or smaller and the aspect ratio of the comparison example 2 was 0.7 or smaller. In contrast to these aspect ratios of the comparison examples, the aspect ratio of the invention was 1.0 or larger. This is because the squeegee 14 of the cartridge-type squeegee head 13 which is disposed relatively to the metal mask 1 so that the longitudinal direction thereof follows the direction which is at right angles to the direction in which the apertures 14 and the bridge portions 5 of the metal mask 1 are arranged is moved relatively to the metal mask 1 along the direction in which the apertures 4 and the bridge portions 5 are arranged. This enables even a metal mask 1 having a mesh aperture of 90% or larger to be adopted.

The invention is not limited to the support table 12, the squeegee 14 and the cleaning mechanism 15 which are used in the embodiment described above, and hence, these constituent members can be modified as required.

This patent application is based on Japanese Patent Application (No. 2010-068254) filed on Mar. 24, 2010, the contents of which are to be incorporated herein by reference.

### DESCRIPTION OF REFERENCE NUMERALS AND CHARACTER

1 metal mask; 3 covering portion; 4 aperture; 5 bridge portion; 10 screen printing apparatus; 11 substrate; 12 support table; 13 squeegee head; 14 squeegee; P paste.

1. A screen printing apparatus for forming a belt-shaped circuit pattern on a surface of a substrate comprising:
a support table for supporting the substrate;
a metal mask having a covering portion for covering a part of the surface of the substrate, a plurality of apertures from which a part of the substrate is exposed and bridge portions provided individually between the apertures along a direction which intersects a longitudinal direction of the circuit patterns; and
a cartridge-type squeegee head for supplying a paste to be the circuit pattern to a surface of the metal mask under a predetermined pressure while causing a squeegee of a predetermined length to slide relatively on an upper surface of the metal mask in a contact fashion.

2. The screen printing apparatus as set forth in claim 1, wherein a lower surface of the bridge portion constitutes a depressed step surface relative to a lower surface of the covering portion.

3. A screen printing method for forming a belt-shaped circuit pattern on a surface of a substrate comprising the steps of:
causing the substrate to be supported on a support table;
placing a metal mask having a covering portion for covering part of the surface of the substrate, a plurality of apertures from which part of the substrate is exposed and bridge portions provided individually between the apertures along a direction which intersects a longitudinal direction of the circuit patterns on a surface of the substrate; and then,
supplying a paste to be the circuit pattern to a surface of the metal mask under a predetermined pressure by a cartridge-type squeegee head while causing a squeegee of a predetermined length to slide relatively on an upper surface of the metal mask in a contact fashion.
